(19) United States
(12) Patent Application Publication
(10) Pub. No.: US 2023/0083497 A1
(43) Pub. Date: Mar. 16, 2023

(54) UNIFORM PLASMA LINEAR ION SOURCE

(71) Applicant: Applied Materials, Inc., Santa Clara, CA (US)

(72) Inventors: Alexandre Likhanskii, Malden, MA (US); Peter F. Kurunczi, Cambridge, MA (US); Ernest E. Allen, Rockport, MA (US)

(73) Assignee: Applied Materials, Inc., Santa Clara, CA (US)

(21) Appl. No.: 17/476,200

(22) Filed: Sep. 15, 2021

(51) Int. Cl. H01J 37/32

(52) U.S. Cl. CPC H01J 37/3211; H01J 37/32715; H01J 2237/20228

(57) ABSTRACT

An ion source. The ion source may include a plasma chamber to house a plasma, and an extraction assembly, disposed along a side of the plasma chamber, and comprising at least one extraction aperture. The ion source may further include an antenna assembly, extending through the plasma chamber, along a first axis. The antenna assembly may include a dielectric enclosure, a plurality of conductive antennae, extending along the first axis within the dielectric enclosure.

### FIELD OF THE DISCLOSURE

The disclosure relates generally to processing apparatus, and more particularly to plasma based ion sources.

### BACKGROUND OF THE DISCLOSURE

In the present day, plasmas are used to process substrates, such as electronic devices, for applications such as substrate etching, layer deposition, ion implantation, and other processes. Some processing apparatus employ a plasma chamber that generates a plasma to act as an ion source for substrate processing. An ion beam may be extracted through an extraction assembly and directed to a substrate in an adjacent chamber. This plasma may be generated in various ways.

In various commercial systems, an antenna is disposed outside the plasma chamber, proximate to a dielectric window. The antenna is then excited using an RF power supply. The electromagnetic energy generated by the antenna then passes through the dielectric window to excite feed gas disposed within the plasma chamber. This configuration provides a relatively simple construction, and may generate dense plasmas suitable for generating a high current ion beam using extraction through an extraction aperture that may be placed centrally within the plasma chamber. However, such plasmas may tend to have a peaked plasma density in the middle of the chamber, and may not be ideal for multi-aperture, high current ion beam systems where two or more apertures are arranged as parallel slots along one edge of the plasma chamber.

In other known approaches, two antennas may be disposed within the plasma chamber, and may be referred to as internal antennas. Like the previous embodiment, an RF power supply is electrically coupled to the internal antennas. These internal antennas each include an outer tube, which tube may be quartz or another dielectric material, to form two antenna structures that extend within the plasma. An electrically conductive coil is disposed within and usually spaced apart from the outer tube. The RF power supply is electrically coupled to the coil, which coil emits electromagnetic energy through the outer tube, generating a plasma within the plasma chamber. However, the plasma that is generated using the two antenna structures may not be of the desired uniformity throughout the plasma chamber. For example, the plasma density may be greater near the internal antenna and may be reduced in regions away from the internal antenna.

This plasma non-uniformity may affect the extracted ion beam. For example, rather than extracting an ion beam having a constant ion density across its width, the ion beam may have a greater concentration of ions in a first portion, such as near the center, than a second portion, such as at its ends.

To address this issue, approaches where the multiple antenna structures may be moved within a plasma have been proposed. However, such approaches may provide a less than robust design, requiring movement of the dielectric outer tubes that house the antenna structures. Moreover, the plasma uniformity generated may still be less than targeted uniformity for multi-aperture processing systems.

With respect to these and other considerations the present disclosure is provided.

### BRIEF SUMMARY

Various embodiments are directed to antenna assemblies, ion sources, and processing apparatus. In one embodiment, an ion source may include a plasma chamber to house a plasma, and an extraction assembly, disposed along a side of the plasma chamber, and comprising at least one extraction aperture. The ion source may further include an antenna assembly, extending through the plasma chamber, along a first axis. The antenna assembly may include a dielectric enclosure, a plurality of conductive antennae, extending along the first axis within the dielectric enclosure.

In another embodiment, a processing system is provided, including a plasma chamber to house a plasma, and an extraction assembly, disposed along a side of the plasma chamber, and comprising at least one extraction aperture. The processing system may also include an antenna assembly, extending through the plasma chamber, along a first axis. The antenna assembly may include a dielectric enclosure, and a plurality of conductive antennae, extending along the first axis within the dielectric enclosure. The processing system may further include a process chamber, adjacent to the extraction assembly, and comprising a substrate stage, scannable along a scan direction, perpendicular to the first axis. The processing system may further include a power generator, connected to the antenna assembly.

In a further embodiment, an antenna assembly for an inductively coupled ion source is provided, including a dielectric enclosure, extending along a first direction from a first end to a second end. The antenna assembly may include a first conductive antenna, extending through the dielectric enclosure, from the first end to the second end; and a second conductive antenna, extending through the dielectric enclosure, from the first end to the second end. As such, at least one of the first conductive antenna and the second conductive antenna may be movable within the dielectric enclosure, along at least a second direction, perpendicular to the first direction.

### BRIEF DESCRIPTION OF THE DRAWINGS

FIG. 1 shows an end view of an exemplary system, in a first configuration, according to embodiments of the disclosure;

FIG. 2A shows an end view an exemplary plasma chamber in a first configuration, according to embodiments of the disclosure;

FIG. 2B shows a top plan view of an extraction assembly, according to embodiments of the disclosure;

FIG. 2C shows a side view the exemplary plasma chamber of FIG. 2A;

FIG. 2D shows a top plan view the exemplary plasma chamber of FIG. 2A;

FIG. 2E shows an end view the exemplary plasma chamber of FIG. 2A in a second configuration, according to embodiments of the disclosure;

FIG. 3A is a composite illustration showing simulated plasma density in a reference plasma chamber having a known antenna configuration;

FIG. 3B is a composite illustration showing simulated plasma density in a plasma chamber having an antenna assembly according to the present embodiments;

FIG. 4A presents an exemplary structure of a dielectric enclosure for an antenna assembly according to one embodiment of the disclosure;

FIG. 4B presents an exemplary structure of a dielectric enclosure for an antenna assembly according to another embodiment of the disclosure;

FIG. 4C presents an exemplary structure of a dielectric enclosure for an antenna assembly according to a further embodiment of the disclosure;

FIG. 4D presents an exemplary structure of a dielectric enclosure for an antenna assembly according to an additional embodiment of the disclosure;

FIG. 5 presents a top plan view of an exemplary antenna configuration for an antenna assembly according to one embodiment of the disclosure;

FIG. 6 presents a top plan view of an exemplary antenna configuration for an antenna assembly according to another embodiment of the disclosure;

FIG. 7 presents an end view of an exemplary antenna assembly according to another embodiment of the disclosure;

FIG. 8 presents a top plan view of an exemplary antenna assembly according to another embodiment of the disclosure; and

FIG. 9 presents a top plan view of another exemplary antenna assembly according to another embodiment of the disclosure.

The drawings are not necessarily to scale. The drawings are merely representations, not intended to portray specific parameters of the disclosure. The drawings are intended to depict exemplary embodiments of the disclosure, and therefore are not be considered as limiting in scope. In the drawings, like numbering represents like elements.

### DETAILED DESCRIPTION

An apparatus, system and method in accordance with the present disclosure will now be described more fully hereinafter with reference to the accompanying drawings, where embodiments of the system and method are shown. The system and method may be embodied in many different forms and are not be construed as being limited to the embodiments set forth herein. Instead, these embodiments are provided so this disclosure will be thorough and complete, and will fully convey the scope of the system and method to those skilled in the art.

Terms such as “top,” “bottom,” “upper,” “lower,” “vertical,” “horizontal,” “lateral,” and “longitudinal” may be used herein to describe the relative placement and orientation of these components and their constituent parts, with respect to the geometry and orientation of a component of a semiconductor manufacturing device as appearing in the figures. The terminology may include the words specifically mentioned, derivatives thereof, and words of similar import.

As used herein, an element or operation recited in the singular and proceeded with the word “a” or “an” are understood as potentially including plural elements or operations as well. Furthermore, references to “one embodiment” of the present disclosure are not intended to be interpreted as precluding the existence of additional embodiments also incorporating the recited features.

Provided herein are approaches for improved plasma uniformity in a processing apparatus, and in particular in compact ion beam processing apparatus. The present embodiments may be suitable for applications where plasma uniformity at the point of extraction of an ion beam is useful across one or more directions.

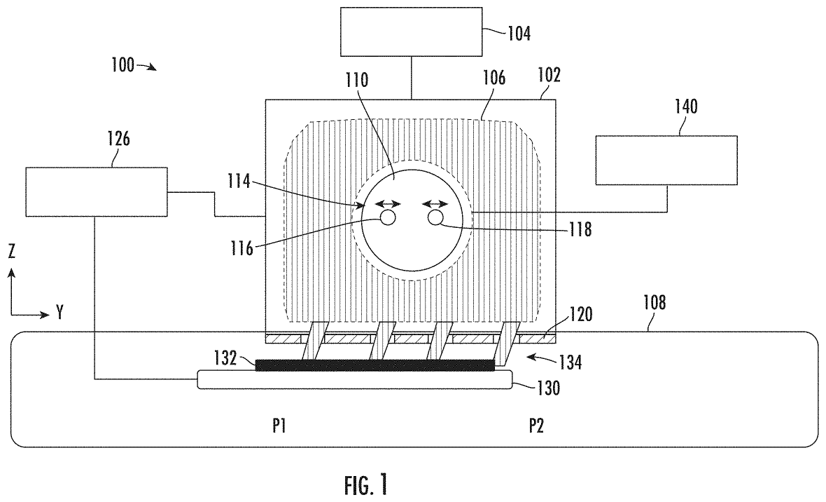

FIG. 1 shows an end view of an exemplary system, in a first configuration, according to embodiments of the disclosure. The system will be referred to herein as processing system 100, and is suitable for ion beam processing of a substrate 132. The system 100 includes a plasma chamber 102 to house a plasma 106, a power generator 104, coupled to deliver power to generate the plasma 106, when a suitable gaseous species (not separately shown) is delivered to the plasma chamber 102. The power generator 104 may be an RF power generator, for example.

In order to process the substrate 132, an extraction assembly 120 is provided along a side of the plasma chamber 102, where the extraction assembly 120 includes at least one extraction aperture that generates a corresponding ion beam, shown as ion beam 134. In the example of FIG. 1, for purposes of explanation, four extraction apertures are illustrated, while any suitable number of extraction apertures may be included in an extraction assembly according to the present embodiments.

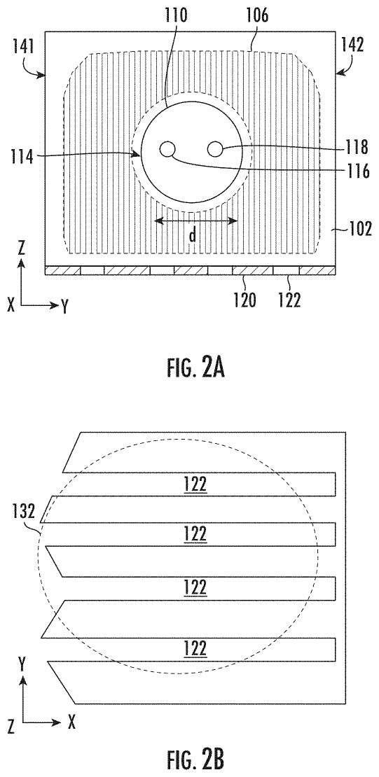

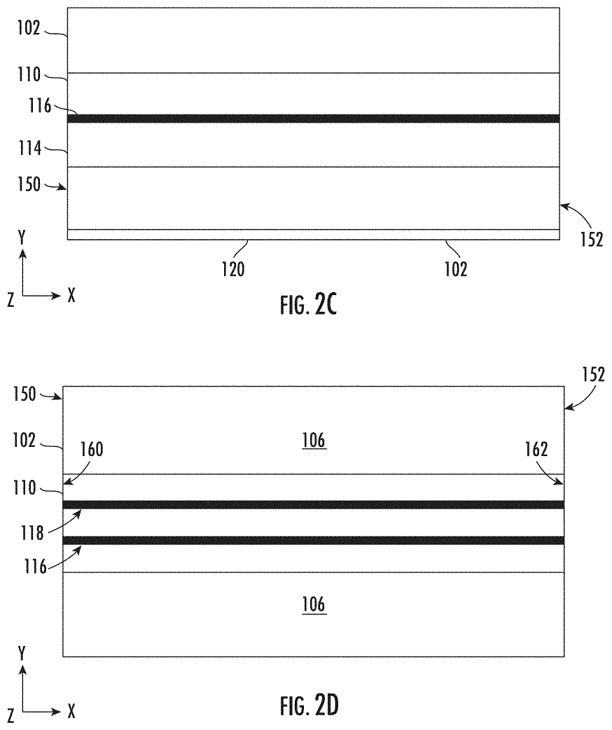

The processing system 100 further includes an antenna assembly 110, where the antenna assembly 110 extends through the plasma chamber 102, along a first axis (in this case, the x-axis of the Cartesian coordinate system shown). Further details of a variant of the antenna assembly 110 are illustrated with respect FIG. 2C and FIG. 2D, discussed below. In brief, the antenna assembly 110 includes a dielectric enclosure 114, which enclosure may be formed of a suitable insulating material (e.g., quartz) that acts as a dielectric window. The antenna assembly 110 may further include a plurality of conductive antennae, extending along the first axis (x-axis) within the dielectric enclosure 114. In the example shown, the plurality of conductive antennae include a first antenna 116 and a second antenna 118.

As such, the power generator 104, plasma chamber 102, antenna assembly 110, and extraction assembly 120 may constitute an ion source, which ion source is used to generate at least one ion beam for processing of the substrate 132. In operation, the power generator 104 is coupled to the first antenna 116 and the second antenna 118, to power the plasma 106, such as through inductive coupling of the first antenna 116 and second antenna 118 to the plasma 106.

More particularly, when process gas is directed into the plasma chamber 102, power is applied to the first antenna 116 and the second antenna 118, such that the plasma 106 is ignited in the plasma chamber 102. For example, with reference to FIG. 2C and FIG. 2D, the first antenna 116 and the second antenna 118 may be connected on a first side 150 of the plasma chamber 102 (directly or through circuitry elements) and may be attached to the power generator 104 on a second side 152 of the plasma chamber 102.

When a bias voltage is applied by an extraction voltage supply 126, between the plasma chamber 102 and substrate 132, or substrate holder 130 (which components may be disposed in a process chamber 108), ion beam(s) 134 are extracted through the extraction apertures 122 (see also FIG. 2B), and are directed to the substrate 132. In different embodiments, the extraction voltage supply 126 may operate to apply a pulsed DC bias voltage or an RF bias voltage, between substrate 132 and plasma chamber 102. Moreover, in some embodiments the extraction assembly 120 may include beam blockers (not shown) as in known plasma processing systems, so as to extract angled ion beams through the extraction apertures 122, where the ion beams 134 may form a non-zero angle of incidence with respect to the substrate normal (z-axis).

Turning now to FIG. 2A, FIG. 2C, and FIG. 2D, there are shown different views of the plasma chamber 102, including the antenna assembly 110. In the view of FIG. 2A, a plasma 106 is present, while for clarity, the plasma 106 is omitted from FIG. 2C and FIG. 2D. As shown in FIG. 2A, the plasma 106 extends around the dielectric enclosure 114. In one implementation, the dielectric enclosure 114 may be located in the middle of the plasma chamber 102 along the y-direction. As such, the plasma 106 may extend generally symmetrically in the y-direction around the dielectric enclosure 114. As shown in FIG. 2C and FIG. 2D, the dielectric enclosure 114 may extend from a first end 160 to a second end 162, entirely from the first side 150 to the second side 152. As such, the antenna assembly 110 may also extend entirely through the plasma chamber 102 from the first side 150 to the second side 152.

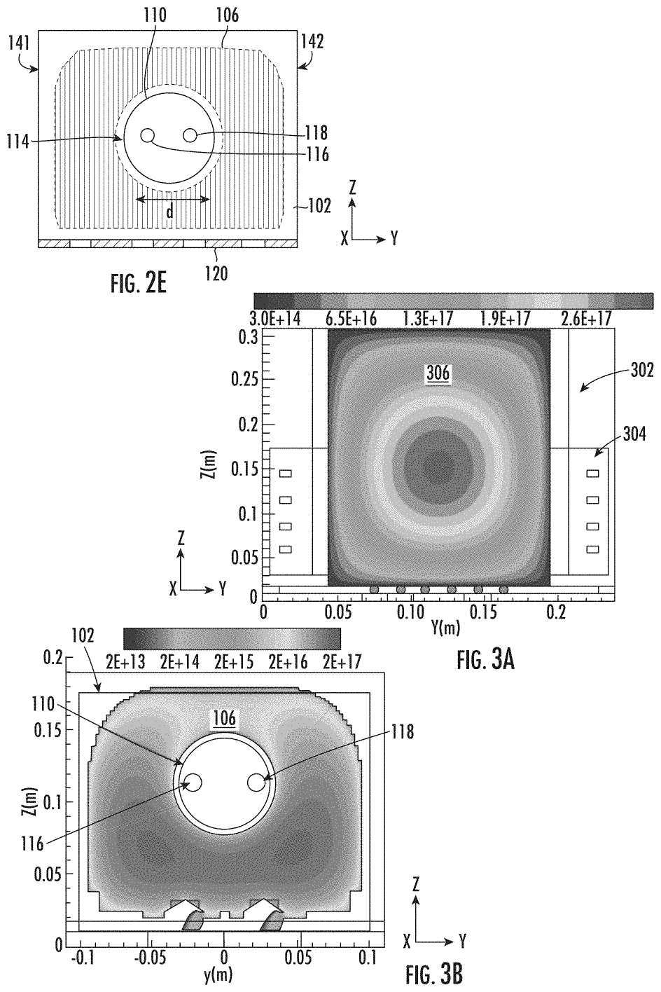

As discussed in more detail with respect to FIG. 3B to follow, the presence of the dielectric enclosure 114 in the middle of the plasma chamber 102 (at least with respect to the y-direction) may tend to modify the shape and distribution of the plasma 106. For example, the presence of the dielectric enclosure 114 may tend to displace dense regions of the plasma 106 outwardly toward the wall 141 and the wall 142. For example, the diameter of the dielectric enclosure 114 may be equivalent of 10% to 50% of the width of plasma chamber 102 along the y-direction according to some non-limiting embodiments. As a result, by displacing a portion of the plasma from the normally dense-plasma middle region, the overall uniformity of the plasma 106 along the y-direction may be improved.

In accordance with various embodiments of the disclosure, the dielectric enclosure 114 may be movable within the plasma chamber 102, such as along the y-axis, or along the z-axis, or along both axes. In this manner, the distribution and uniformity of the plasma 106 may be adjusted.

In some embodiments, at least one antenna of the plurality of antennae within a dielectric enclosure may be movable within the dielectric enclosure 114. In other words, the at least one antenna may be independently movable within respect to the walls of the dielectric enclosure 114, either along the y-axis, along the z-axis, or along both axes. In particular embodiments, both the first antenna 116 and the second antenna 118 may be movable within the dielectric enclosure 114. Said differently, the first antenna 116 and the second antenna 118 may be independently movable within respect to the walls of the dielectric enclosure 114, either along the y-axis, along the z-axis, or along both axes. In various embodiments, the first antenna 116 and the second antenna 118 may be independently movable within respect to the walls of the dielectric enclosure 114, and may be independently movable, one antenna with respect to the other antenna, either along the y-axis, along the z-axis, or along both.

As an example, in FIG. 2A the first antenna 116 and second antenna 118 may be movable within the dielectric enclosure 114 along the y-axis to an extent indicated by the arrow d, nearly the diameter of the dielectric enclosure 114. For example, the first antenna 116 and the second antenna 118 may be movable toward opposite walls of the dielectric enclosure, thus increasing the space between the first antenna 116 and second antenna 118, or alternatively, may be brought into close proximity to one another, as shown in the configuration of FIG. 2E.

In particular embodiments, the antenna assembly 110, or similar assembly, may be coupled to a movement mechanism 140, as depicted in FIG. 1, where the movement mechanism 140 is coupled to move the first antenna 116, second antenna 118, dielectric enclosure 114, or any combination of these elements, in concert with one another, or in relative motion with respect to one another. The movement mechanism 140 may be, for example, an external motor, an actuator, a mechanical lever, a slide, or a magnetic component, according to some non-limiting embodiments. As such, the movement mechanism 140 may provide a convenient approach for manipulating the relative position of these components of the antenna assembly 110 within the plasma chamber 102.

By providing for relative movement of the first antenna 116 and the second antenna 118 within the dielectric enclosure 114, the distribution and density of the plasma 106 may be conveniently manipulated. To further illustrate this point, FIG. 3A provides a composite illustration showing simulated plasma density in a reference plasma chamber having a known antenna configuration, while FIG. 3B provides a composite illustration showing simulated plasma density in a plasma chamber having an antenna assembly according to the present embodiments. In the illustration of FIG. 3A, an external antenna assembly 304 circumferentially surrounds a plasma chamber 302, to generate a plasma 306 therein. The plasma chamber 302 is superimposed over an image of the plasma 306 shown in cross-section along a y-z plane, where the plasma density is indicated by the different shading. As shown, the density varies from the 3E14/cm³ range on the extreme outer edges of the plasma chamber 302, to mid E17/cm³ in the center of the plasma chamber 302.

In the illustration of FIG. 3B, an antenna assembly 110 is disposed within the plasma chamber 102, as generally described above. The plasma chamber 102 is superimposed over an image of the plasma 106 shown in cross-section along a y-z plane, where the plasma density is indicated by the different shading. As shown, the density in most of the plasma 106 varies from the E16/cm³ range to E17/cm³ range, where the plasma density is generally higher toward the lower portion of the plasma chamber 102.

More germane to uniformity concerns for substrate processing, the uniformity of plasma density along the y-direction along the lower edge of a plasma chamber is improved in the example of FIG. 3B. More particularly, in the example of FIG. 3A, the uniformity where ion beam extraction takes place is 18.5% along the Y-axis, while the uniformity in FIG. 3B along the y-axis where ion beam extraction takes place is 1%, where the uniformity may be expressed as: Maximum Extracted Current Value−Minimum Extracted Current Value)/Average Extracted Current Value.

Turning in detail to FIG. 3B, this composite illustration highlights several features afforded by the present embodiments. In this example, the diameter of the dielectric enclosure 114 is approximately 7 cm, affording a large volume to accommodate relative displacement of the first antenna 116 and the second antenna 118. This relative movement facilitates the ability to modulate the inductive coupling of the first antenna 116 and/or the second antenna 118 to the plasma 106, disposed outside the dielectric enclosure 114, and thus provides a convenient manner to manipulate the density and distribution of the plasma 106. In the particular example shown, the antennae are laterally displaced from one another by approximately 5 cm. In other embodiments, depending upon the gas species, plasma power, and other factors, the relative position of the antennae may be changed, such as placing the antennae closer to one another or at a different position along the z-axis, so as to adjust the plasma density uniformity accordingly.

With reference again to FIG. 1, for applications where uniform ion beam processing across a substrate 132 is called for, in operation, the extraction aperture(s) 122 may be elongated along the x-axis, such as to an extent to cover an entirety of the substrate 132 along the X-direction as shown. For example, in some non-limiting embodiments, the extraction aperture(s) may have a width on the order of several millimeters to several centimeters along the y-direction, and a length along the x-direction of tens of centimeters. To cover an entire substrate, such as a semiconductor wafer having a diameter of tens of centimeters, the substrate holder 130 may be scanned along the Y-axis so an extraction aperture 122 may be scanned across an entirety of the substrate 132 in the y-direction, thus exposing an entirety of the substrate 132 to an ion beam 134.

To increase beam current that is applied to the substrate 132, a plurality of extraction apertures 122 are provided in a plasma chamber 102 according to embodiments of the disclosure. Thus, the beam current directed to the substrate 132 will be equal to the sum of beam currents directed through the individual extraction apertures. Note that in circumstances where the beam current is uniform across the x-axis, by virtue of scanning the entirety of the substrate 132 under the whole extraction assembly from point P1 to point P2, for example, the substrate 132 will be exposed to a uniform ion dose. This result is true even in circumstances where plasma density is non-uniform along the y-direction, as in FIG. 3A, resulting in different beam current impinging on the substrate 132 from different extraction apertures. The reason why the beam dose across the substrate 132 would be uniform when exposed to different apertures having different beam current is because the beam current is uniform in the X-direction. Moreover, each point of the substrate 132 along the y-direction is exposed sequentially to the same apertures, resulting in the total ion dose impinging on any region of the substrate 132 after exposure to all the apertures being the same. Thus, to achieve dose uniformity in a scanned substrate exposed to a multi-extraction aperture plasma chamber, the plasma density along the x-direction should be uniform, while along the y-direction need not be uniform in principle.

However, in circumstance such as the known device of FIG. 3A where plasma density is non-uniform along the y-direction, the ion beams extracted from the different extraction apertures may differ from one another in additional ways besides the different beam current. The present inventors have realized that in various extraction aperture assemblies, the angle of ions, and the average angle of incidence of an extracted ion beam is proportional to plasma density in the plasma chamber. The shape of the plasma meniscus that develops at the extraction aperture is dependent upon plasma density, such that the average angle of an ion beam exiting the plasma 106 across the plasma meniscus, as well as the range of angles of incidence (angular spread) varies with plasma density. Thus, in a non-uniform plasma chamber as in FIG. 3A, a multi-extraction aperture extraction plate may place some extraction apertures at an outer position of relatively lower plasma density, where the angle of incidence of the ion beams differs from the angle of incidence of ion beams extracted through an extraction aperture located in a middle region of high density region of the plasma chamber. The embodiment of FIG. 3B, by providing 1% uniform plasma density along the Y-direction facilitates both increased beam current as well as more uniform angle of incidence of ions striking the substrate 132 through the different apertures, since the plasma density and meniscus shape is nearly constant as a function of position along the Y-axis.

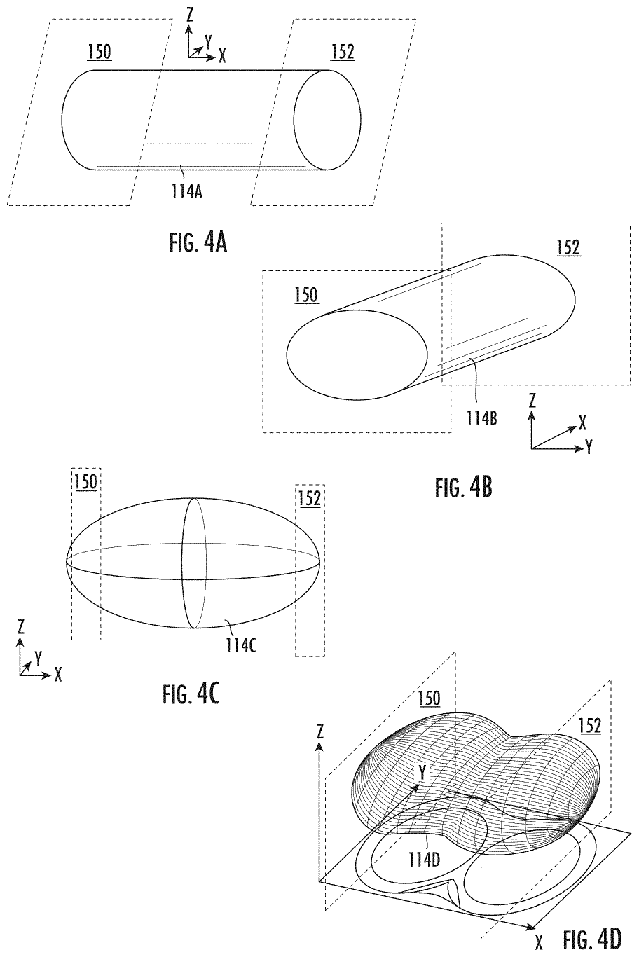

According to further embodiments of the disclosure, the shape of the dielectric enclosure of an antenna assembly may be modified to further modify plasma density within a plasma chamber. FIG. 4A presents an exemplary structure of a dielectric enclosure for an antenna assembly according to one embodiment of the disclosure. In this embodiment, the dielectric enclosure 114A has the shape of a circular cylinder. FIG. 4B presents an exemplary structure of a dielectric enclosure 114B for an antenna assembly according to another embodiment of the disclosure. In this embodiment the dielectric enclosure 114B has the shape of a cylinder with an elliptical cross-section, elongated along the Y-direction, which elongation may be useful to adjust plasma uniformity in the Y-direction.

FIG. 4C presents an exemplary structure of a dielectric enclosure for an antenna assembly according to a further embodiment of the disclosure. In this embodiment the dielectric enclosure 114C has an ellipsoid shape to increase plasma density near walls of a plasma chamber, both in X- and Y-directions. FIG. 4D presents an exemplary structure of a dielectric enclosure for an antenna assembly according to an additional embodiment of the disclosure. In this embodiment, the dielectric enclosure 114D has a double sphere shape/inverted ellipsoid shape to create higher plasma density in a central region of a plasma chamber.

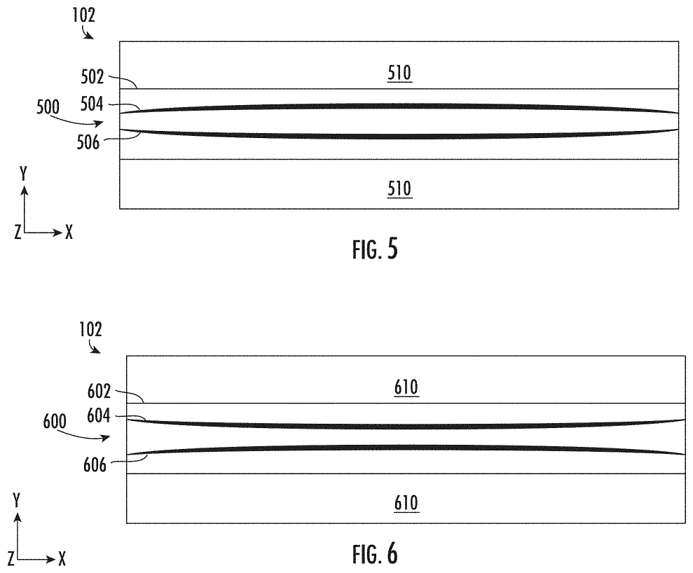

In some embodiments, a pair of conductive antennae may be arranged within a dielectric enclosure, where the pair of antennae are disposed closer to one another in a middle portion. To illustrate this point, FIG. 5 presents a top plan view of an exemplary antenna configuration for an antenna assembly according to one embodiment of the disclosure. An embodiment of a plasma chamber 102 is shown, where the antenna assembly 500 includes a dielectric enclosure 502. The dielectric enclosure 502 may be elongated having walls extending along the X-direction as shown. A pair of conductive antennae are shown as antenna 504 and antenna 506, having an arcuate shape, where the pair of conductive antennae are curved in the X-Y plane, so that the pair are disposed closer to one another at respective distal ends of the pair of conductive antennae, meaning in the region near the walls of the plasma chamber 102 extending along the Y-axis. Said differently, the pair of conductive antennae are disposed further apart from one another in the middle region, resulting in the pair of conductive antennae being closer to the walls of dielectric enclosure 502, and thus closer to plasma 510. Accordingly, this configuration may tend to increase plasma density in a middle region of the plasma chamber along the x-axis.

FIG. 6 presents a top plan view of an exemplary antenna configuration for an antenna assembly according to another embodiment of the disclosure.

An embodiment of a plasma chamber 102 is shown, where the antenna assembly 600 includes a dielectric enclosure 602. The dielectric enclosure 602 may be elongated having walls extending along the X-direction as shown. A pair of conductive antennae are shown as antenna 604 and antenna 606, where the pair of conductive antennae are curved in the X-Y plane, so that the pair are disposed closer to one another in a middle region of the pair of conductive antennae, meaning in the middle region of the plasma chamber 102 extending along the Y-axis. Said differently, the pair of conductive antennae are disposed further apart from the walls of dielectric enclosure 602, and thus further from plasma 610, in the middle region. Accordingly, this configuration may tend to increase plasma density toward the end walls of the plasma chamber 102, meaning near the walls extending along the Y-axis. In accordance with various embodiments of the disclosure, the antennae of the configurations depicted in FIG. 5 or FIG. 6 may be rotatable around the x-axis, so the relative proximity between two different antennae along the x-axis may be readily changed. For example, the different configurations of FIG. 5 and FIG. 6 may be achieved by mutual rotation of the same curved antennae around the x-axis.

To further manipulate plasma density according to the present embodiments, an antenna assembly may include a ferromagnetic insert, disposed within a dielectric enclosure. FIG. 7 presents an end view of an exemplary antenna assembly according to another embodiment of the disclosure. In this example, an antenna assembly 710 is provided extending along the x-axis within a plasma chamber 102, as generally described above with respect to FIGS. 1 and 2A-2D. In addition to the first antenna 116 and antenna 118, the antenna assembly 710 includes a ferromagnetic insert assembly 712, disposed within the dielectric enclosure 114. The ferromagnetic insert assembly 712 may include just one ferromagnetic insert, or may include a plurality of ferromagnetic inserts according to different embodiments of the disclosure. In the embodiment depicted in FIG. 7, the ferromagnetic insert assembly 712 is disposed between the first antenna 116 and the second antenna 118, and may accordingly reduce coupling between the first antenna 116 and the second antenna 118. This reduced coupling will increase efficiency of the plasma chamber 102 in operation.

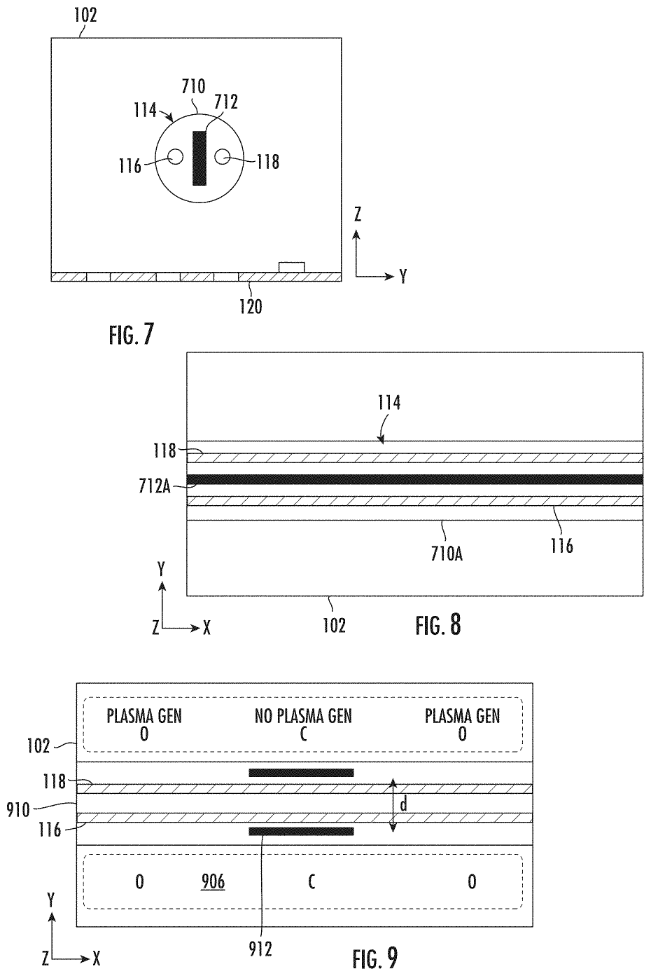

FIG. 8 presents a top cross-sectional plan view of an exemplary antenna assembly according to another embodiment of the disclosure. In this example, the antenna assembly 710A may be as generally described with respect to FIG. 7, where the ferromagnetic insert assembly is disposed between first antenna 116 and second antenna 118. In this example, a ferromagnetic insert assembly 712A includes just one piece, extending along the X-axis throughout the dielectric enclosure 114, so as to block coupling between the first antenna 116 and second antenna 118 along an entirety of the dielectric enclosure 114 along the x-axis.

FIG. 9 presents a top cross-sectional plan view of another exemplary antenna assembly according to another embodiment of the disclosure. In this example, the antenna assembly 910 includes a ferromagnetic insert 912, shaped as a ferromagnetic cylinder that surrounds a middle portion of the first antenna 116 and second antenna 118, in order to reduce inductive coupling with the plasma 906 in the middle portion. In this manner, plasma generation in the center C of the plasma chamber 102 (in X direction) is reduced while plasma generation near edges O (y-axis walls) is increased. In the example shown, the plasma density at the edges O may or may not be larger than the plasma density in the center C. In particular, plasma will still form in the center C even though inductive coupling from the first antenna 116 and second antenna 118 is blocked by the ferromagnetic cylinder. In one example, the plasma formation from the conductive antennae in center C may be reduced in density relative to the plasma formation in the edges O to counter the increased plasma density in the center C that would otherwise occur, leading to a more uniform plasma density along the x-direction.

Moreover, in addition to adjusting plasma density along the x-direction with the use of the ferromagnetic insert 912, in the embodiment of FIG. 9, the first antenna 116 and second antenna 118 are movable along the y-axis within a range indicated by “d” in order to adjust plasma density uniformity along the y-direction.

Note that the aforementioned embodiments have emphasized the ability to improve plasma uniformity by adjusting placement and shape of dielectric enclosure, of placement of antennae, as well as placement of ferromagnetic inserts within a single large dielectric enclosure. However, the same embodiments provide the ability to tune plasma non-uniformity by adjustment of the same components, in cases where a targeted non-uniform plasma density is useful for substrate processing.

In view of the above, the present disclosure provides at least the following advantages. As a first advantage, the present embodiments provide easy access to conductive antennae within a single, large dielectric enclosure, for maintenance or placement purposes. As a second advantage, the tuning of plasma density within a plasma chamber is facilitated by providing easy adjustment to the position of conductive antennae within a dielectric enclosure. Additionally a further advantage is the reduced footprint of a plasma chamber afforded by placement of the antenna assembly within the plasma chamber. Another advantage is the ability to readily place and adjust the configuration of ferromagnetic components within a dielectric enclosure for further plasma density tuning.

While certain embodiments of the disclosure have been described herein, the disclosure is not limited thereto, as the disclosure is as broad in scope as the art will allow and the specification may be read likewise. Therefore, the above description are not to be construed as limiting. Those skilled in the art will envision other modifications within the scope and spirit of the claims appended hereto.

1. An ion source, comprising:
a plasma chamber to house a plasma;
an extraction assembly, disposed along a side of the plasma chamber, and comprising at least one extraction aperture; and
an antenna assembly, the antenna assembly extending through the plasma chamber, along a first axis, the antenna assembly comprising:
a dielectric enclosure; and
a plurality of conductive antennae, extending along the first axis within the dielectric enclosure.

2. The ion source of claim 1, wherein the at least one extraction aperture is elongated along a first direction, and
wherein the plurality of conductive antennae are movable with respect to one another within the dielectric enclosure along at least a second direction, perpendicular to the first direction.

3. The ion source of claim 2, wherein the at least one extraction aperture comprises a plurality of extraction apertures, elongated along the first direction.

4. The ion source of claim 1, wherein the extraction assembly comprises an extraction plate, disposed within a first plane, and wherein the plurality of conductive antennae have an arcuate shape, within a second plane, parallel to the first plane.

5. The ion source of claim 4, wherein the plurality of conductive antennae comprise a pair of antennae, wherein the pair of antennae are disposed closer to one another in a middle portion.

6. The ion source of claim 4, wherein the plurality of conductive antennae comprise a pair of antennae, wherein the pair of antennae are disposed closer to one another at respective distal ends of the pair of antennae.

7. The ion source of claim 1, further comprising a ferromagnetic insert assembly, disposed within the dielectric enclosure.

8. The ion source of claim 7, wherein plurality of conductive antennae comprise a pair of antennae, and wherein the ferromagnetic insert assembly extends between a first antenna of the pair of antennae and a second antenna of the pair of antennae.

9. The ion source of claim 1, further comprising a movement mechanism, coupled to move at least one antenna of the plurality of conductive antennae with respect to another antenna of the plurality of antennae, within the dielectric enclosure.

10. A processing system, comprising:
a plasma chamber to house a plasma;
an extraction assembly, disposed along a side of the plasma chamber, and comprising at least one extraction aperture;
an antenna assembly, the antenna assembly extending through the plasma chamber, along a first axis, the antenna assembly comprising:
a dielectric enclosure; and
a plurality of conductive antennae, extending along the first axis within the dielectric enclosure;
a process chamber, adjacent to the extraction assembly, and comprising a substrate stage, scannable along a scan direction, perpendicular to the first axis; and
a power generator, connected to the antenna assembly.

11. The processing system of claim 10, wherein the at least one extraction aperture is elongated along a first direction, and wherein the plurality of conductive antennae are movable with respect to one another within the dielectric enclosure along at least a second direction, perpendicular to the first direction.

12. The processing system of claim 11, wherein the at least one extraction aperture comprises a plurality of extraction apertures, elongated along the first direction.

13. The processing system of claim 10, wherein the extraction assembly comprises an extraction plate, disposed within a first plane, and wherein the plurality of conductive antennae have an arcuate shape, within a second plane, parallel to the first plane.

14. The processing system of claim 13, wherein the plurality of conductive antennae comprise a pair of antennae, wherein the pair of antennae are disposed closer to one another in a middle portion.

15. The processing system of claim 13, wherein the plurality of conductive antennae comprise a pair of antennae, wherein the pair of antennae are disposed closer to one another at respective distal ends of the pair of antennae.

16. The processing system of claim 10, further comprising a ferromagnetic insert assembly, disposed within the dielectric enclosure.

17. The processing system of claim 16, wherein the plurality of conductive antennae comprise a pair of antennae, and wherein the ferromagnetic insert assembly extends between a first antenna of the pair of antennae and a second antenna of the pair of antennae.

18. The processing system of claim 10, further comprising a movement mechanism, coupled to move at least one antenna of the plurality of conductive antennae with respect to another antenna of the plurality of antennae, within the dielectric enclosure.

19. An antenna assembly for an inductively coupled ion source, comprising;
a dielectric enclosure, extending along a first direction from a first end to a second end;
a first conductive antenna, extending through the dielectric enclosure, from the first end to the second end; and
a second conductive antenna, extending through the dielectric enclosure, from the first end to the second end,
wherein at least one of the first conductive antenna and the second conductive antenna are movable within the dielectric enclosure, along at least a second direction, perpendicular to the first direction.

20. The antenna assembly of claim 19, further comprising a ferromagnetic insert assembly, disposed within the dielectric enclosure.
